(19) United States
(12) Patent Application Publication
(10) Pub. No.: US 2005/0087141 A1
(43) Pub. Date: Apr. 28, 2005

(54) Production method and production device for thin film

(76) Inventors: Kazuyoshi Honda, Takatsuki-shi (JP); Yoriko Takai, Toyonaka-shi (JP); Sadayuki Okazaki, Katano-shi (JP); Junichi Inaba, Toyonaka-shi (JP); Syuuji Itoh, Nara-shi (JP); Hiroshi Higuchi, Kyotanabe-shi (JP); Hitoshi Sakai, Nagoya-shi (JP)

Correspondence Address: Merchant & Gould, PO Box 2903, Minneapolis, MN, 55402-0903, US

(21) Appl. No.: 10/509,463

(22) PCT Filed: Mar. 24, 2003
(86) PCT No.: PCT/JP03/03557

(30) Foreign Application Priority Data
Mar. 26, 2002 (JP) 2002-86797

(51) Int. Cl. C23C 16/00; C23C 14/30

(52) U.S. Cl. 118/726; 427/596; 427/248.1

(57) ABSTRACT

An electron beam evaporation source (42) that contains a first thin film material, an electron beam source (44) that emits an electron beam (45) to be used to evaporate the first thin film material by heating, and a resistance heating evaporation source (48) for evaporating a second thin film material by heating using a resistance heating method are arranged so that the electron beam (45) passes through a vapor stream of the second thin film material. Thus, evaporated atoms of the second thin film material can be ionized. As a result, a thin film having improved properties and increased mechanical strength can be formed. Further, since it is no longer necessary to use another device for ionizing the evaporated atoms of the second thin film material, the complication of a configuration and a cost increase can be prevented.

### TECHNICAL FIELD

The present invention relates to a method and apparatus for manufacturing a thin film.

### BACKGROUND ART

As the age of information and communication progresses, thin films have been finding wider application. With this as a background, developments also have been made rapidly in the composition of a thin film and the processes for manufacturing a thin film on a daily basis.

As a representative process for manufacturing a thin film, a vapor deposition method has been known. Among the widely used vapor deposition methods for heating evaporation materials are a resistance heating method and an electron beam heating method.

Meanwhile, a thin film can be provided with various properties by simultaneously evaporating various kinds of materials from different evaporation sources and allowing them to adhere to a common area to be vapor-deposited. In this manner, a thin film having a desired composition can be formed (see, for example, JP 1(1989)-117208 A). In this case, as one possible method for heating the materials, all of the materials are heated by the resistance heating method. As another possible method for heating the materials, all of the materials are heated by the electron beam heating method. As still another possible method for heating the materials, the resistance heating method and the electron beam heating method are performed in combination.

Generally, the electron beam heating method requires greater cost and larger-scale equipment. In contrast to this, the resistance heating method is more convenient and cost-effective, thereby achieving excellent mass productivity in the industrial field. Thus, in many cases, combined methods including the resistance heating method have been used.

However, while in the resistance heating method, evaporated atoms resulting from heating a vapor-deposition material are only allowed to adhere on a surface to be vapor-deposited, in the electron beam heating method, evaporated atoms resulting from heating are ionized to be activated by an electron beam. Therefore, a thin film obtained by the electron beam heating method exhibits excellent properties in terms of the size of a crystal and the density compared with a thin film obtained by the resistance heating method. Thus, when forming a thin film made of various kinds of materials, the combined methods including the resistance heating method have presented a problem of, for example, a decrease in the mechanical strength of the obtained thin film.

### DISCLOSURE OF THE INVENTION

The present invention has as its object to provide a method and apparatus for manufacturing a thin film that can solve the above-mentioned problem caused by the use of the resistance heating method and improve the mechanical strength of a thin film simply and cost-effectively. In the method and apparatus according to the present invention, a thin film containing a first thin film material and a second thin film material is formed in such a manner that the first thin film material and the second thin film material are evaporated by heating using the electron beam heating method and the resistance heating method, respectively.

In order to achieve the above-mentioned object, the present invention has the following configuration.

A method for manufacturing a thin film according to the present invention is a method for manufacturing a thin film containing a first thin film material and a second thin film material on a surface to be vapor-deposited by vacuum vapor deposition. In the method, the first thin film material and the second thin film material are evaporated by heating using an electron beam heating method and a resistance heating method, respectively, and an electron beam to be used to heat the first thin film material is passed through a vapor stream of the second thin film material.

Furthermore, an apparatus for manufacturing a thin film according to the present invention includes an electron beam evaporation source that is arranged so as to face a surface to be vapor-deposited and contains a first thin film material, an electron beam source that emits an electron beam to be used to evaporate the first thin film material by heating using an electron beam heating method, and a resistance heating evaporation source that is arranged so as to face the surface to be vapor-deposited and evaporates a second thin film material by heating using a resistance heating method. In the apparatus, the electron beam evaporation source, the electron beam source and the resistance heating evaporation source are arranged so that the electron beam passes through a vapor stream of the second thin film material.

### BRIEF DESCRIPTION OF THE DRAWINGS

FIG. 1 is a schematic diagram showing a configuration of an embodiment of an apparatus for manufacturing a thin film according to the present invention.

FIG. 2 is a schematic diagram showing a configuration of an apparatus for manufacturing a thin film according to comparative examples.

### BEST MODE FOR CARRYING OUT THE INVENTION

According to the above-described method and apparatus for manufacturing a thin film according to the present invention, an electron beam to be used to heat the first thin film material passes through a vapor stream resulting from evaporating the second thin film material by heating using the resistance heating method, thereby allowing evaporated atoms of the second thin film material to be ionized. As a result, a thin film having improved properties and increased mechanical strength can be formed. Further, it is no longer necessary to use another device for ionizing the evaporated atoms of the second thin film material, thereby simplifying the configuration and reducing costs.

Hereinafter, the present invention will be described in detail with reference to the appended drawings.

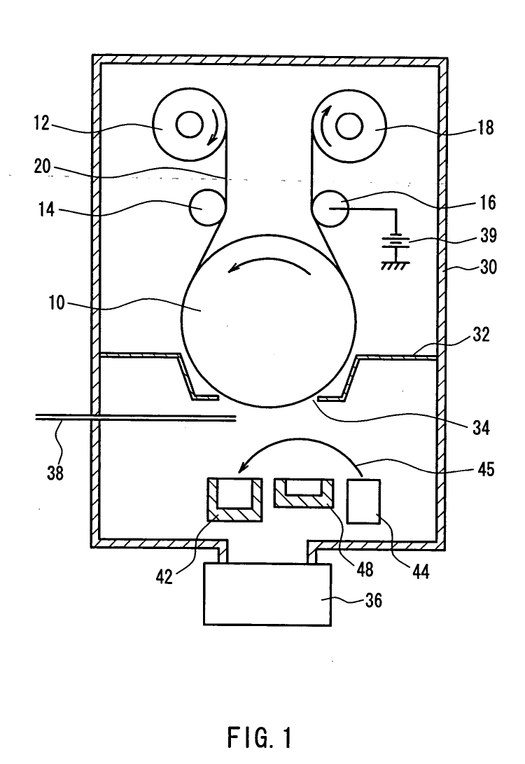

FIG. 1 is a schematic diagram showing a configuration of an embodiment of an apparatus for manufacturing a thin film according to the present invention.

A long belt-shaped supporting base 20 unwound from an unwinding roll 12 passes along an unwinding side guide roll 14 and is conveyed along an outer peripheral face of a cylindrical can roller 10 that is rotated in a direction indicated by an arrow. Then, the supporting base 20 passes along a winding side guide roll 16 and is wound by a winding roll 18.

Below the can roller 10, an electron beam evaporation source 42 that contains a first thin film material used for forming a thin film, a resistance heating evaporation source 48 for evaporating a second thin film material by heating using the resistance heating method, and an electron beam source 44 that emits an electron beam 45 to be used to evaporate the first thin film material in the electron beam evaporation source 42 by heating using the electron beam heating method, are arranged in this order. In practical use, it may be necessary to use other devices such as a magnetic field application device for allowing the electron beam 45 from the electron beam source 44 to impinge on the first thin film material in the electron beam evaporation source 42, which are not shown.

Reference numerals 30 and 32 denote a vacuum container and a partition wall dividing an inner portion of the vacuum container 30, respectively. Further, reference numerals 34 and 36 denote an opening that is provided in the partition wall 32 so that a lower portion of the can roller 10 can be exposed and a vacuum pump for maintaining the inside of the vacuum container 30 at a predetermined degree of vacuum, respectively. Further, reference numerals 38 and 39 denote a gas nozzle for introducing a reactive gas into an evaporated atom stream and a bias device that applies a bias voltage to the winding side guide roll 16, respectively.

The description is directed next to an operation of the apparatus for manufacturing a thin film according to the present invention with the above-described configuration.

While the supporting base 20 is conveyed along the can roller 10, the first thin film material in the electron beam evaporation source 42 and the second thin film material in the resistance heating evaporation source 48 are evaporated by heating, respectively. As a result, evaporated atoms of the first thin film material and evaporated atoms of the second thin film material are allowed to adhere on the supporting base 20 exposed inside the opening 34, thereby allowing a thin film made of the first thin film material and the second thin film material to be formed.

In the present invention, the electron beam evaporation source 42 and the electron beam source 44 are arranged so as to interpose the resistance heating evaporation source 48 between them. Therefore, the electron beam 45 from the electron beam source 44 sequentially passes through a vapor stream of the second thin film material emitted from the resistance heating evaporation source 48 and a vapor stream of the first thin film material emitted from the electron beam evaporation source 42. This allows both of evaporated atoms of the second thin film material and evaporated atoms of the first thin film material to be ionized. As described above, in the present invention, evaporated atoms of the second thin film material from the resistance heating evaporation source 48 also can be ionized. Conventionally, such evaporated atoms are not ionized. As a result, a thin film having improved properties can be formed. For example, the mechanical strength of the thin film can be increased.

As long as the electron beam evaporation source 42, the electron beam source 44 and the resistance heating evaporation source 48 are arranged so that the electron beam 45 passes though a vapor stream of the second thin film material from the resistance heating evaporation source 48, the arrangement of these elements is not limited to the arrangement shown in FIG. 1. It is preferable that as shown in FIG. 1, the electron beam evaporation source 42, the electron beam source 44 and the resistance heating evaporation source 48 are arranged substantially on the same plane for the following reason. That is, this arrangement makes it easier to allow the electron beam 45 to pass through a vapor stream of the first thin film material and a vapor stream of the second thin film material.

There is no particular limit to the first and second thin film materials. For example, the first and second thin film materials can be made of Li, Co, Mn, P, Cr or the like. A thin film that can be formed has a composition represented by, for example, LiCoO₂, LiPON or the like. For example, Co can be used for the first thin film material, and Li can be used for the second thin film material.

The supporting base 20 is formed, for example, of metal foil or a resin sheet. The metal foil can be formed of foil made of stainless steel, copper, nickel or the like. The resin sheet can be formed of a sheet made of, for example, polyethylene terephthalate.

Further, in the case of using metal or the like as the thin film materials, it is preferable that in forming a thin film, a negative voltage (bias voltage) is applied to the winding side guide roll 16 by using the bias device 39. The winding side guide roll 16 is in contact with a surface of the supporting base 20 on a side on which the thin film is formed. Accordingly, the same negative bias voltage also is applied to a surface to be vapor-deposited of the supporting base 20 inside the opening 34 through the thin film having conductivity. As a result, an ion (for example, a metal ion) originating in an evaporated atom ionized by the electron beam 45 is allowed to adhere to the surface to be vapor-deposited in a high-energy state. Thus, a thin film that is improved in strength, density, crystallinity and the like can be formed. As long as a bias voltage can be applied to the surface to be vapor-deposited, a means for applying the voltage is not limited to the configuration shown in FIG. 1. For example, it also may be possible to apply a bias voltage to the can roller 10. Alternatively, it also may be possible to use a conductive material for the supporting base 20 and apply a bias voltage to this supporting base 20. Further, the polarity of a bias voltage is only required to be reverse to the polarity of the evaporated atom that has been ionized and is not limited to the negative polarity as described above.

Furthermore, when forming a thin film, it is possible to perform reactive vapor deposition by introducing a reactive gas from the gas nozzle 38 toward an area on which the thin film is to be formed. In the present invention, evaporated atoms of the second thin film material from the resistance heating evaporation source 48 also are ionized, thereby allowing the reaction with a reactive gas to be improved. There is no particular limit to the material of the reactive gas, and oxygen, nitrogen or the like can be used.

### EXAMPLES

### (Example 1)

Using the manufacturing apparatus shown in FIG. 1, a Ni—Cr thin film was formed on the supporting base 20 in the following manner.

That is, as the supporting base 20, a polyethylene terephthalate film of 20 μm thickness was allowed to travel along the water-cooled can roller 10. Cr in the electron beam evaporation source 42 was heated by the electron beam 45 from the electron beam source 44, and Ni in the resistance heating evaporation source 48 was subjected to resistance heating. In this case, a reactive gas was not supplied from the gas nozzle 38, and a bias voltage was not applied by the bias device 39.

In the above-described manner, the Ni—Cr thin film of 5 μm thickness containing 80% Ni and 20% Cr was formed on the supporting base 20.

### (Comparative Example 1)

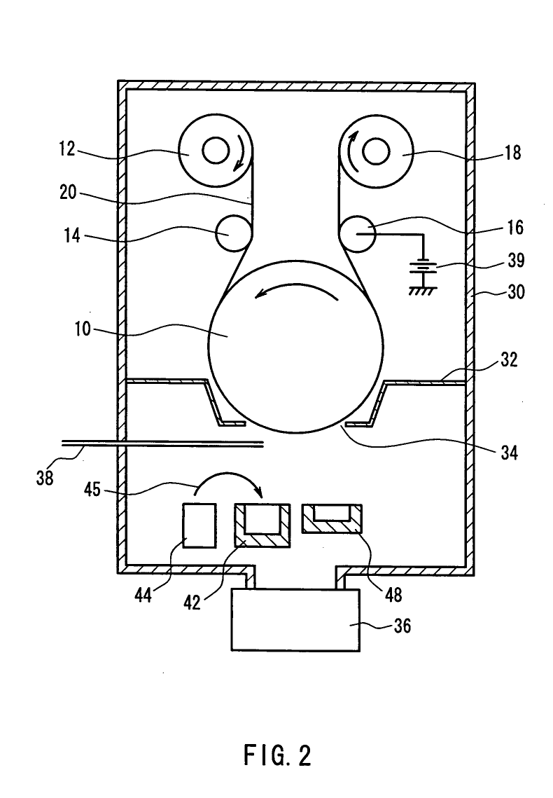

Using a manufacturing apparatus shown in FIG. 2, a Ni—Cr thin film was formed on the supporting base 20. The apparatus shown in FIG. 2 has the same configuration as that of the apparatus shown in FIG. 1 except that the arrangement of the electron beam evaporation source 42, the electron beam source 44 and the resistance heating evaporation source 48 is different. In FIG. 2, like reference numerals indicate like constituent elements that are the same as those shown in FIG. 1, for which duplicate descriptions are omitted. In the apparatus shown in FIG. 2, an electron beam 45 from an electron beam source 44 reaches an electron beam evaporation source 42 without passing through a vapor stream of a thin film material from a resistance heating evaporation source 48. Accordingly, evaporated atoms from the resistance heating evaporation source 48 never can be ionized.

Using an apparatus having the above-described configuration, a Ni—Cr thin film of 5 μm thickness containing 80% Ni and 20% Cr was formed on a supporting base 20 under exactly the same conditions as those in the case of Example 1.

[Evaluation]

With respect to each of the thin films of Example 1 and Comparative Example 1, the peel strength was determined.

The determination was made in the following manner. That is, each thin film was incised in the form of a grid with a pitch of 2 mm by using a razor. Then, an adhesive tape (“Scotch Mending Tape”, a trademark of Sumitomo 3M Limited) was attached to each thin film and was subsequently peeled slowly. At this time, the number of pieces of each thin film peeled from the supporting base 20 (assuming that the parameter was 100) was determined.

As a result, while the number of peeled pieces of Example 1 was 13, in the case of Comparative Example 1, the number was 45.

Conceivably, in Example 1, Ni atoms evaporated by the resistance heating method were ionized by an electron beam, and thus the improved peel strength was attained.

### (Example 2)

Using the manufacturing apparatus shown in FIG. 1, a LiCo—O thin film was formed on the supporting base 20 in the following manner.

That is, as the supporting base 20, a stainless steel sheet of 10 μm thickness was allowed to travel along the water-cooled can roller 10. While Co in the electron beam evaporation source 42 was heated by the electron beam 45 from the electron beam source 44, Li in the resistance heating evaporation source 48 was subjected to resistance heating. Vapor deposition was performed by supplying an oxygen gas from the gas nozzle 38. A bias voltage was not applied by the bias device 39.

In the above-described manner, the LiCo—O thin film of 2 μm thickness containing Co and Li at a ratio of 1 to 1 was formed on the supporting base 20.

### (Comparative Example 2)

Using the manufacturing apparatus shown in FIG. 2, a LiCo—O thin film of 2 μm thickness containing Co and Li at a ratio of 1 to 1 was formed on the supporting base 20 under exactly the same conditions as those in the case of Example 2.

[Evaluation]

With respect to each of the thin films of Example 2 and Comparative Example 2, the scratch strength was determined.

The determination was made in the following manner. That is, the supporting base on which a thin film was formed was fixed on a level surface, and under a load, a stylus having a radius of 15 μm was brought into contact with the thin film. The stylus was allowed to oscillate at an amplitude of 10 μm and a frequency of 30 Hz. The load to be applied to the stylus was increased gradually, and a load with which a breaking flaw was caused in the thin film was determined as the scratch strength.

As a result, while Example 2 had a value represented by 0.49×10⁻³N (5 gf), Comparative Example 2 had a value represented by 0.20×10⁻³N (2 gf).

In Example 2, conceivably, Li atoms evaporated by the resistance heating method were ionized by an electron beam, and thus the improved scratch strength was attained.

The embodiments disclosed in this application are intended to illustrate the technical aspects of the invention and not to limit the invention thereto. The invention may be embodied in other forms without departing from the spirit and the scope of the invention as indicated by the appended claims and is to be broadly construed.

For example, although in each of the examples described above, the present invention was applied to continuous winding vapor deposition in which the surface to be vapor-deposited was formed of a traveling substrate in the shape of a long film, the present invention is not limited thereto. The surface to be vapor-deposited also may be formed of, for example, a traveling substrate in the shape of a sheet or a stationary substrate. The substrate can be formed of a polymer material or a material such as metal, semimetal, glass, ceramic or the like, and further can be formed of a composite material of these materials.

When forming a thin film, it also is possible to use the elements in combination with other elements such as an ion generating source and an electron generating source. For example, an ion gun, a plasma gun and other forms of electron guns can be used. Further, when forming a thin film, it also may be possible to perform ultraviolet or infrared irradiation, or irradiation by using various kinds of lasers such as a carbonic acid gas laser, a YAG laser, an excimer laser, and a semiconductor laser. By performing such irradiation, an evaporation material can be improved in an ionization rate, reactivity, adhesion to a film and the like, and the crystallinity of the evaporation material and a surface property of a film and the like can be controlled.

The application of a bias voltage also is not limited to that in the examples described above. A bias voltage to be applied can be a direct voltage, an alternating voltage or a combination of these voltages, and bias voltages having various waveforms and voltage values can be used. This allows thin films to be formed so as to have properties varying in a thickness direction. A bias voltage to be applied also may be adjusted by controlling not only a voltage value but also a current value, which is particularly useful with respect to variations of an evaporation source.

In the resistance heating method, heating also may be performed by the use of a heater, a lamp or a boat, or by the induction heating or the like. In the electron beam heating method, an electron gun having a deflection angle of 90 degrees, 180 degrees, 270 degrees or the like and an axial electron gun can be used. When an ion plating method in which iron excitation caused by induction is applied to the resistance heating method is used in combination with the electron beam heating method according to the present invention, an ionization rate can be increased, and thus it is possible to achieve various forms of improvements in properties and advantages in terms of production.

As for a method of producing a vacuum, as long as the method can attain the degree of vacuum at which vapor deposition using electron beams can be performed, various methods and combinations of those methods can be used. For example, vacuum can be produced by the use of a cryopump, an oil diffusion pump, a turbo pump, an ion pump or the like. However, the present invention is not limited to the use of these pumps.

In most cases, the introduction of a gas enhances the effect of the present invention and in no cases, causes the effect to be deteriorated.

Furthermore, in the present invention, it is possible to monitor an evaporation state. Since an evaporation material is ionized, an evaporation state of the material can be monitored by an optical means utilizing plasma light emission. It is particularly useful to monitor an evaporation state by an optical means so that evaporation states of two or more elements can be evaluated independently, and exhibits high adaptability to the present invention.

1. A method for manufacturing a thin film, the thin film containing a first thin film material and a second thin film material, in which the thin film is manufactured on a surface to be vapor-deposited by vacuum vapor deposition,
wherein the first thin film material and the second thin film material are evaporated by heating using an electron beam heating method and a resistance heating method, respectively, and
an electron beam to be used to heat the first thin film material is passed through a vapor stream of the second thin film material.

2. The method according to claim 1, wherein a reactive gas is introduced in a portion on the surface to be vapor-deposited in which the thin film is to be formed.

3. The method according to claim 1, wherein a bias voltage is applied to the surface to be vapor-deposited.

4. The method according to claim 1, wherein the first thin film material is Co, and the second thin film material is Li.

5. An apparatus for manufacturing a thin film, comprising:
an electron beam evaporation source that is arranged so as to face a surface to be vapor-deposited and contains a first thin film material;
an electron beam source that emits an electron beam to be used to evaporate the first thin film material by heating using an electron beam heating method; and
a resistance heating evaporation source that is arranged so as to face the surface to be vapor-deposited and evaporates a. second thin film material by heating using a resistance heating method,
wherein the electron beam evaporation source, the electron beam source and the resistance heating evaporation source are arranged so that the electron beam passes through a vapor stream of the second thin film material.

6. The apparatus according to claim 5, wherein the electron beam evaporation source, the resistance heating evaporation source and the electron beam source are arranged in this order.

7. The apparatus according to claim 5, further comprising a nozzle for introducing a reactive gas in a portion on the surface to be vapor-deposited in which the thin film is to be formed.

8. The apparatus according to claim 5, further comprising a bias device for applying a bias voltage to the surface to be vapor-deposited.

9. The apparatus according to claim 5, wherein the electron beam evaporation source, the electron beam source and the resistance heating evaporation source are arranged substantially on the same plane.
